(19) United States
(12) Patent Application Publication
(10) Pub. No.: US 2013/0048812 A1
(43) Pub. Date: Feb. 28, 2013

(54) FLAT PANEL MOUNTING SYSTEM

(71) Applicant: Anthony LOZANO, San Jose, CA (US)

(72) Inventor: Anthony LOZANO, San Jose, CA (US)

(21) Appl. No.: 13/550,992

(22) Filed: Jul. 17, 2012

Related U.S. Application Data
(60) Provisional application No. 61/527,350, filed on Aug. 25, 2011.

(51) Int. Cl. H05K 7/00; A44B 18/00

(52) U.S. Cl. 248/220.22

(57) ABSTRACT

A flat panel mounting system and package includes a wall cleat with a planar wall cleat plate and an angled wall cleat flange. The wall cleat plate is securable to a wall surface and is adapted to be leveled. Two spaced flat panel cleats are securable to attachment holes in the rear of a flat panel device. The flat panel cleats each have a plurality of holes to accommodate different flat panel attachment hole screw sizes. Each flat panel cleat has a flange that is angled at a complimentary manner to the wall cleat flange. Each one of the wall cleat flange and the flat panel cleat flange are provided with one component of a hook and loop fastening system. A flat panel mounting package for the flat panel mounting system includes all of the hardware components necessary to accomplish mounting of the flat panel device to a wall surface.

### CROSS-REFERENCE TO RELATED APPLICATIONS

This application claims priority to U.S. provisional patent application No. 61/527,350, filed Aug. 25, 2011, the disclosure of which is expressly incorporated herein by reference.

### FIELD OF THE INVENTION

The present invention is directed generally to a flat panel television or video display mounting system. More particularly, the present invention is directed to a flat panel television or video display wall mounting system. Most specifically, the present invention is directed to a flat panel television or video display panel mounting system which is usable with all flat panel televisions and video display panels within a specific size range. The system includes a wall cleat that is securable to two or more spaced adjacent wall studs. A pair of mounting cleats are securable to the rear of virtually any flat panel television or video display panel within a defined size range using the VESA holes provided on the rear of such a flat panel television or video display panel. The wall cleat and the flat panel mounting cleats are each provided with cooperatively engageable flanges that each carry one component of a commercial hook and loop fastening material such as VELCRO®. Any television or video display panel within the defined size range can be securely positioned on a supporting wall, in a simple, expeditious manner by use of the mounting system in accordance with the present invention.

### DESCRIPTION OF THE PRIOR ART

Flat panel television and video display panels have virtually replaced prior rear projection television and cathode ray tube systems. These high definition television and video display panels provide much greater picture quality and clarity than could ever be provided by their predecessors.

Initially, all such flat panel televisions and video displays were provided with a support base which would allow the television or video display to be positioned atop a cabinet that was also used to support ancillary equipment such as a cable box, a video player or a DVR system, a surround sound system and the like. As the flat panels themselves have improved and their associated ancillary components have decreased in size, the need for such a support cabinet has diminished. Additionally, in a variety of installation situations, such as in apartment buildings, hotels, other multi-unit facilities and in commercial usage, the flat panel television receiver or the video display panel may receive all of its information through one single cable connection without the need for on-site auxiliary devices.

The trend has been to the greater utilization of wall mounting arrangements for flat panel televisions and video monitors. Such mounting arrangements free up counter space and provide greater flexibility in flat panel location. If the flat panel device can be mounted on a wall, the ancillary support devices, such as a cable box, a video or a DVR player, a surround sound system and the like can be positioned in a somewhat remote location. The size of the cabinet that may be required to support these ancillary components, whose size continues to be reduced, is much less than would be required to provide adequate support area to position the stand required to properly support, for example, a 55 inch flat screen television panel.

While the desire to mount flat panel televisions and video panels on a planar wall surface has increased substantially, the hardware required to accomplish such a task has remained relatively difficult and cumbersome to use. Too frequently, a skilled installation technician has been required to properly secure the flat panel television or the video panel to the wall itself. The mounting assemblies have been somewhat bulky and heavy and often do not provide an installation which will allow the flat screen panel to be flat against the supporting wall. Such prior flat panel installation systems have often utilized cumbersome, heavy brackets that were modifications of devices originally used to mount conventional cathode ray television systems in hospital rooms and the like. Their attempted modification, to allow them to support current flat panel televisions, has not been aesthetically pleasing and has been unnecessarily complex and expensive.

Often, the flat panel television or video display mounting systems that have previously been available, have required the attachment of large supports to the wall on which the television or video panel is to be mounted. Such supports have required the drilling of numerous holes and/or the removal of large portions of the wall board or other wall-forming surfaces. Whether these installations have taken place in a private residence, a condominium, a rental apartment, a multiunit facility such as a hotel or in a commercial setting, there has often been the need to make extensive and thus also expensive repairs to the wall system. Such repairs have acted as a deterrent to the mounting of flat panel televisions and video panels on a wall surface.

The flat panel mounting system in accordance with the present invention, as will be described subsequently, overcomes the limitations of the prior systems. It is a substantial advance in the art.

### SUMMARY OF THE INVENTION

It is an object of the present invention to provide a flat panel mounting system.

Another object of the present invention is to provide a flat panel mounting system adaptable to a wide variety of flat panel televisions and video panels.

A further object of the present invention is to provide a flat panel mounting system which requires minimal wall modification.

Still another object of the present invention is to provide a flat panel mounting system which is uncomplicated and easy to install.

Yet a further object of the present invention is to provide a flat panel mounting system which allows the secure yet easily removable mounting of the flat panel device.

Even still another object of the present invention is to provide a flat panel mounting system in which an angle of inclination of the flat panel, with respect to the wall surface to which it is mounted, can be varied.

As will be described in greater detail in the Description of the Preferred Embodiments which is set forth subsequently, the flat panel mounting system, in accordance with the present invention, is usable with virtually all flat panel devices, within a size range of 32 inches to 55 inches and manufactured in the last several years.

A single wall cleat is securable to at least two spaced wall studs, using a pair of wood screws or sheet metal screws, which are provided as a part of the system. The wall cleat is intended to be installed in a level manner. However, it has the ability to adapt to errors that may be made during its installation. The wall cleat has an upwardly and outwardly facing wall cleat flange which is provided with one component of a commercially available hook and loop fastener, such as VELCRO®. The wall cleat can be slid somewhat longitudinally along the wall to which it is secured in case the desired location of the flat panel device to be mounted is not directly aligned between two spaced wall studs.

Current flat panel televisions and other video panel devices, at least those in the range of 32 inches to 55 inches, are provided with a pair of spaced threaded bores on their rear surface. The sizes of these threaded bores and their spacing are standardized by VESA, the Video Electronics Standard Association. These bores are sized to receive one of three or four different sized mounting screws, depending on the size of the television. This configuration is utilized, in accordance with the present invention, to attach two small flat panel mounting cleats to the rear of the television. Each of these two small flat panel mounting cleats has a downwardly and outwardly extending mounting cleat flange that is provided with a complementary component of the hook and loop fastener that is provided on the upwardly facing surface of the wall cleat flange. Once these two components are brought together, the flat panel television or the video panel is securely, yet releasably attached to the wall.

The wall cleat portion of the flat panel mounting system in accordance with the present invention is adapted to be attachable to spaced vertical wall studs of various spacings. This will allow the wall cleat to be used with conventional 16 inch spaced studs, as well as with other wall studs spacing from 12 inches to 22 inches. The wall cleat can be attached to either wooden studs or to metal studs by using the appropriate ones of the wood screws and the sheet metal screws which are included as part of the system. The mounting holes provided in the wall cleat allow lateral movement of the wall cleat to facilitate positioning of the flat panel at a location other than aligned directly between two spaced studs. The flat panel mounting system in accordance with the present invention overcomes the limitations of numerous ones of the prior systems. It has been configured to mount flat panels of between 32 inches and 55 inches to any wall surface in a straightforward, uncomplicated manner. In contrast to prior systems, that have often been adaptations of mounting systems that were initially configured to be used with rear projection and CRT televisions, the mounting system of the present invention is structured specifically for use with flat panel devices. As such, it is thinner and less cumbersome that such prior adaptations. It provides a much thinner, sleeker finished mount that is very difficult to detect.

The mounting system in accordance with the present invention requires the drilling of only two very small holes in the wall surface. If the system is to be removed at a later date, there is very little wall repair that is required. There is no large-scale cutting of the wall surface material. Only the patching of two small screw holes is required.

The wall cleat of the present mounting system will allow for the correction of minor errors in off-level installations of the wall cleat. As will be discussed in the Description of the Preferred Embodiment, this is accomplished by the provision of wall cleat leveling slots. If an installer, such as a homeowner, should fail to install the wall cleat in a completely level manner, the provision of the wall cleat leveling slots will facilitate the correction of such an error in a quick, easy manner, without completely removing the wall cleat.

The provision of the complimentary hook and loop fastener components on the cooperating flanges of the wall cleat and of the two separate flat panel mounting cleats provides a secure attachment between the two cleat components, while still allowing some horizontal adjustments of the flat panel on the wall. The combination of the ability of the wall cleat to be moved laterally, and the ability of the flat panel device to be positioned somewhat off-center with respect to the wall cleat, provides a great deal of horizontal positional flexibility. In contrast to prior systems that have dictated that the flat panel be mounted spaced equidistantly from the two wall studs, in the present system, there is sufficient flexibility to allow the flat panel to be positioned based on user desire and not completely dictated by wall stud spacing.

The flat panel mounting system in accordance with the present invention is supplied to the user with all of the various mounting hardware. It includes wood screws and sheet metal screws for use in accordance with the type of wall studs. The flat panel mounting cleats have several diameter apertures which will receive selected ones of also supplied attachment screws which are provided in different sizes to fit virtually all of the VESA hole sizes in recently manufactured flat screen panels. A wall spacer is provided and can be secured to one of the two spaced wall studs to which the wall cleat will be attached. This wall spacer will position the flat panel generally parallel to the wall surface. Omission of the wall spacer will provide a tilt of the flat panel, with respect to the wall of approximately 6°. In either mounting configuration, there is sufficient space behind the flat panel device to allow for the connection of the necessary HDMI cabling, the power cord and any other cabling which might be required for ancillary equipment.

The use of hook and loop fastening components to join the wall cleat flange and the flat panel cleat flanges eliminates direct metal to metal contact. The slight gap provided by the hook and loop fastening components, together with the use of a rubber or resilient wall spacer, substantially eliminates noise and vibration transmission from the flat panel television or video panel to the wall. This is particularly an advantage in multi-unit dwellings or other facilities, such as condominiums, apartment buildings, hotels and the like.

The flat panel mounting system in accordance with the present invention overcomes the limitations of the prior art. It is a substantial advance in the art.

### BRIEF DESCRIPTION OF THE DRAWINGS

While the novel features of the flat panel mounting system, in accordance with the present invention, are set forth with particularity in the appended claims, a full and complete understanding of the present invention may be had by referring to the Detailed Description of the Preferred Embodiments, as set forth subsequently, and as depicted in the accompanying drawings, in which:

FIG. 1 is a perspective view of a first preferred embodiment of a flat panel mounting system in accordance with the present invention, depicted in dash lines, and usable to support a flat panel device on a wall;

FIG. 2 is an exploded perspective view of the flat panel mounting system itself;

FIG. 3 is a cross-sectional, side elevation view of the flat panel mounting system taken along line 3-3 of FIG. 1 and showing use of the system with a wall having wooden wall studs;

FIG. 4 is a cross-sectional view taken along line 4-4 of FIG. 1 and showing the cooperating wall cleat and flat panel cleat, the resilient wall spacer and the associated flat panel power cable and HDMI cable connections;

FIG. 5 is a cross-sectional view and showing the attachment of the wall cleat to a wall constructed with sheet metal wall studs;

FIG. 6 is an exploded view of the entire flat panel mounting system in accordance with the present invention and depicting included tools;

FIG. 7A is a schematic depiction of the wall cleat in accordance with the present invention and showing the wall cleat mounted in a first, non-level orientation;

FIG. 7B is a subsequent view of the wall cleat shifted laterally to the left to effect correction of its non-level mounting;

FIG. 7C is a subsequent view of the wall cleat now properly level and secured in such a level position; and

FIG. 8 is a perspective view of a second preferred embodiment of the flat panel mounting system in accordance with the present invention and depicting a wall cleat usable for securement to three spaced wall studs.

### DESCRIPTION OF PREFERRED EMBODIMENTS

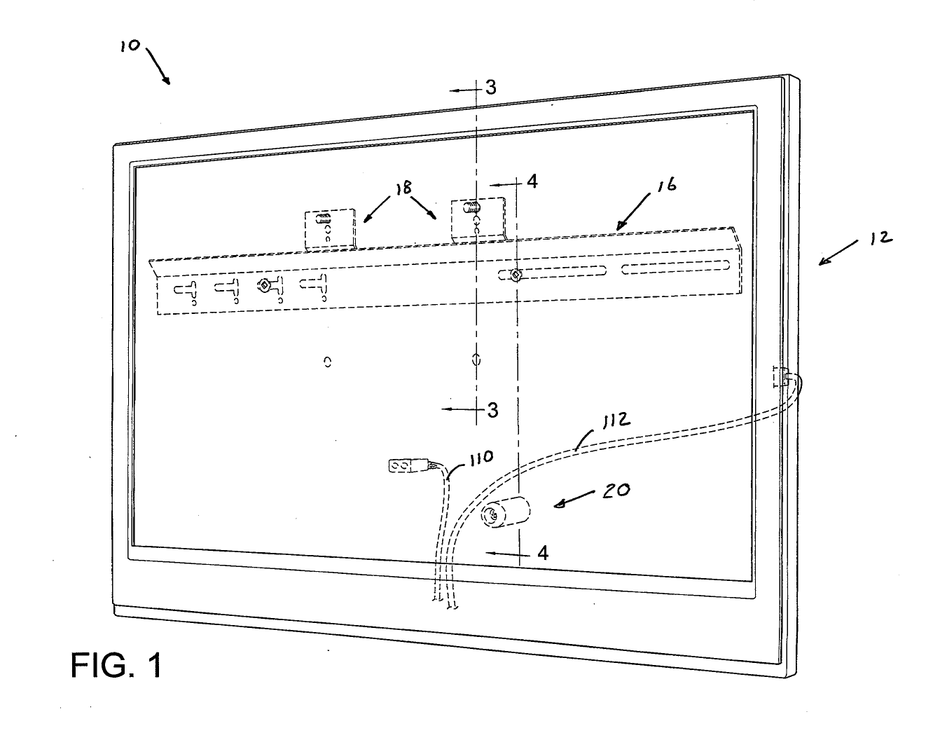

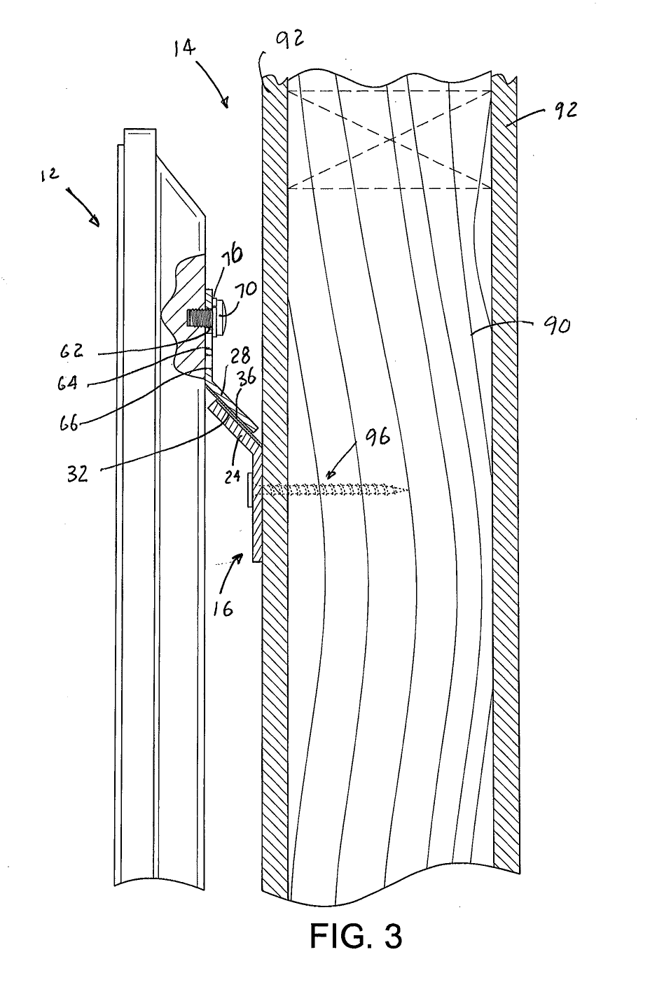

Turning initially to FIG. 1, there may be seen, generally at 10, a first preferred embodiment of a flat panel television mounting system in accordance with the present invention. The mounting system, generally at 10 is intended for use to attach a flat panel television or video monitor, hereinafter a flat panel device, such as the one depicted schematically at 12 in FIG. 1, to a wall surface, such as the vertical wall surface 14 shown in FIGS. 3, 4 and 5. The wall surface 14 will be understood to preferably be a vertical wall surface of any room or area to which a flat panel device would typically be attached. While attachment of such flat panel devices to an interior wall of a living area of a dwelling is the most typical installation locale, it is clearly not the only environment in which such a flat panel device could be installed using the flat panel mounting system in accordance with the present invention.

The flat panel device depicted in FIG. 1 is shown oriented in a “landscape” position. It will be understood that such a flat panel device, either a flat panel television or a flat panel video display could also be mounted in a “portrait” position, which is not specifically depicted. In either orientation, the mounting system, generally at 10, functions in the same manner. The only difference is in the orientation of the flat panel display device.

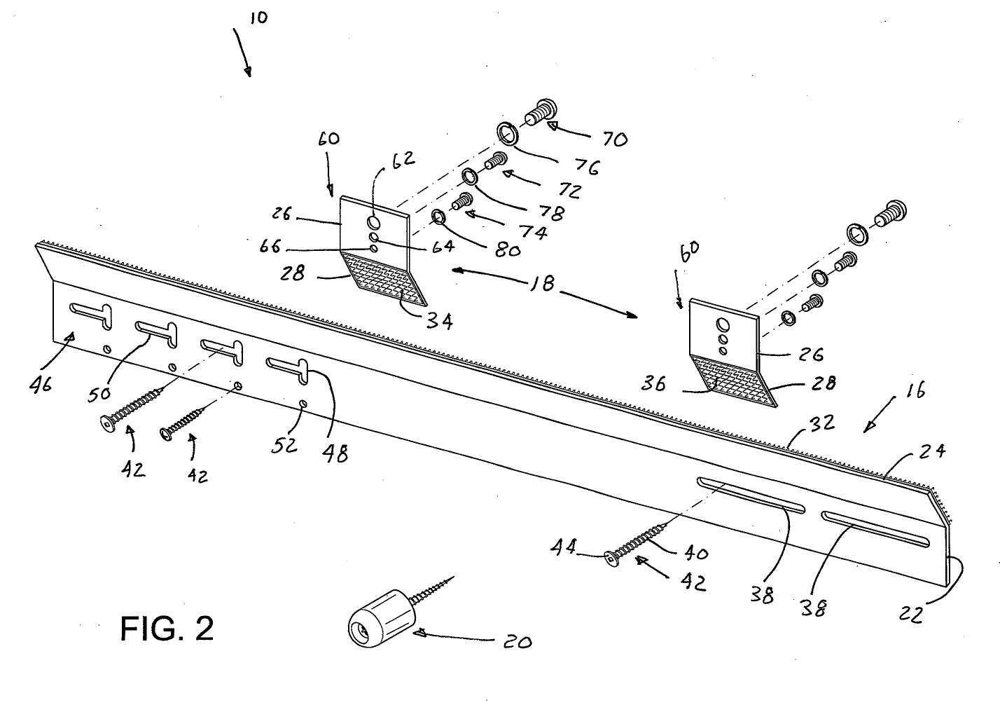

Referring again to FIG. 1, and as may also be seen in FIG. 2, the flat panel mounting system, generally at 10 and in accordance with the present invention, includes a wall mounting cleat, generally at 16, a pair of spaced flat panel mounting cleats 18 and a resilient wall spacer 20. The wall mounting cleat, generally at 16 and the cooperatively shaped flat panel mounting cleats 18 together form what is referred to generally as a “French cleat” arrangement. The wall mounting cleat 16 has a planar wall cleat plate 22 and a wall cleat flange 24. In a similar fashion, the flat panel mounting cleats 18 each have a flat panel cleat plate 26 and a flat panel cleat flange 28. The wall cleat flange 24 and the flat panel cleat flanges 28 are angled with respect to their plates 22 and 26; respectively at similar angles which may be in the range of 30° to 60° from the vertical, with an angle of 45° being preferred.

An inwardly facing surface 30 of the wall cleat flange 24 is provided with one component 32 of a hook and loop fastening system. The cooperating outwardly facing surface 34 of each of the flat panel cleat flanges 28 is provided with the second component 36 of such a hook and loop fastener. A commonly available hook and loop fastening system, such as VELCRO® is preferred for this use. As is well known, such a VELCRO® system is provided with each of the two components 32 and 36 being in the form of a strip or tape with an adhesive layer on the side of the strip or tape opposite to the respective hook or loop component. Such VELCRO® systems are well known and need not be described in greater detail. They are adhesively attached to the respective flange surfaces 30 and 34; respectively with sufficient adhesive force so that the hook and loop component will separate from each other more readily than will each respective component separate from the flange face to which it has been adhesively bonded.

The wall cleat, generally at 16, is, as its name applies, intended to be secured to a wall, and specifically to two or more spaced wall studs that underlie a wall surface such as sheet rock or wall board, as will be described shortly. A wall cleat plate 22 is provided, at a first end, with at least two transversely spaced, generally horizontally extending linear wall cleat slots 38. Each such linear wall cleat slot 38 has a slot width adapted to receive a shank 40 of a securement screw 42 but not sufficient to allow passage therethrough of a head 44 of such a securement screw.

A second, opposite end of the wall cleat plate 22 is provided with several such as 3, T-shaped wall cleat slots 46. These slots 46 may also be referred to as wall cleat leveling slots 46, as will be discussed below. Each such wall cleat leveling slot 46 is generally T-shaped and includes a slot head 48 and a slot leg 50. The head 48 of each such leveling slot 46 is generally transverse to the length of the wall cleat plate 22 whereas the slot leg 50 is generally parallel to the length of the wall cleat plate. Again, as was the case with the linear wall cleat slots 38, each of the T-shaped or leveling wall cleat slots 46 has a slot width sufficient to allow passage of a screw shank 40 of the securing screw, but not to allow passage of the head 44 thereof. Each of the leveling slots 46 is associated with a level establishment aperture 52. One of these level establishment apertures 52 is positioned directly beneath the slot head 44 of each of the T-shaped wall cleat slots 46. The use of each such level establishment aperture 52 will be described subsequently. It is to be understood that each such level establishment aperture 52 is sized to receive the shank 44 of one of the securement screws 42.

Referring again to FIG. 2, it will be seen that each of the flat panel cleats 18, in its flat panel cleat plate 26, is provided with several vertically spaced flat panel attachment holes 60. In the embodiment depicted in FIG. 2, there are provided three such individual flat panel attachment holes 62, 64 and 66. These three individual holes are vertically aligned, generally in the center of each flat panel cleat plate 26 and are of differing diameters. The upper hole 62, which has the largest diameter, is sized to receive a metric screw identified as an M-8 screw 70. The middle hole 64 has an intermediate diameter sized to receive either an M-5 or a M-6 screw 72. The lowest of the three depicted individual flat panel attachment holes 66 is sized to receive an M-4 attachment screw 74. As is known to those of skill in the flat panel art, the Video Electronic Standard Association or VESA® has established a set of guidelines for television and other flat panel mounting hole patterns. Most manufacturers of flat panel television monitors and of video display panels tend to follow the guidelines established by VESA®. The screw sizes set forth above, and their associated individual flat panel attachment holes 62-66, that are provided on each flat panel cleat plate 26, are intended to ensure that each flat panel cleat plate 26 can be securely fastened to the rear of the vast majority of 32 inch −55 inch flat panel televisions and video display panels currently being manufactured. If future flat panel televisions or video display panels have different screw requirements, the holes 62-66 in accordance with the present invention can be sized to accommodate such screw sizes. The several screw sizes set forth above are believed to be usable with virtually all of the currently available flat panel television and video display panel manufacturers. However, the specific sizes thereof as set forth above, are intended to be exemplary and not limiting.

Each of the several sized screws 70-74 is provided with a cooperatively sized lock washer 76, 78 or 80, respectively. Again, these lock washers 76-80 are sized to cooperate with the various flat panel attachment screws 70 to 74. If the sizes of the screws are changed, then obviously the sizes of their associated lock washers will change.

Referring now to FIG. 3, there is depicted an illustration of the attachment of a flat panel device, generally at 12 to a wall surface 14, in accordance with one embodiment of the present invention. In the embodiment depicted in FIG. 3, the wall, generally at 14, is constructed using a plurality of spaced wooden wall studs, such as the stud depicted at 90. Such wall studs are typically placed at 16 inch centers and are used to support wall panels 92 such as gypsum board, wall board, or the like. As may be seen in FIG. 3, the wall cleat 16 is attached to the wall stud 90 by the use of a typical wood screw 96. Such a wood screw 96 is one of the securement screws 42 depicted in FIG. 2. It will be understood that typically two such securement screws 42 such as the wood screw 96 depicted in FIG. 3, will be used to attach the wall cleat 16 to the wall 14 in a generally level orientation.

As may be seen in FIGS. 1 and 2, for example, each of the linear wall cleat slots 38, of which two are provided in the wall cleat 16 depicted in FIGS. 1 and 2, and each of the T-shaped wall cleat slots 46, of which there are provided three in the wall cleat 16, have sufficient linear slot length to accommodate the securement of the wall cleat 16 between two adjacent wall studs 90. The wall cleat 16 configuration depicted in FIGS. 1 and 2 is appropriate for use with wall stud spacings of between 14-24 inches. To install one of the wall cleats 16, the location of two adjacent wall studs 90 can be determined, typically using a commercially available studfinder. Once the two adjacent studs have been located and marked, a hole is drilled in the left stud at a desired mounting height for the flat panel device. The wall cleat 16 is then attached to this left stud by passing a securement screw 42 through the appropriate left T-shaped wall cleat slot 46. Refer to FIG. 1 for a schematic depiction. It is to be noted that the wall cleat 16 does not have to be mounted so that it is positioned centered on the two adjacent wall studs 90. It may be appropriate to not center the wall cleat 16 between the two adjacent studs since the controlling factor is the positioning of the flat panel device on the wall. As seen in FIG. 1, such panel centering may be best accomplished by not centering the wall cleat 16 between two adjacent wall studs 90.

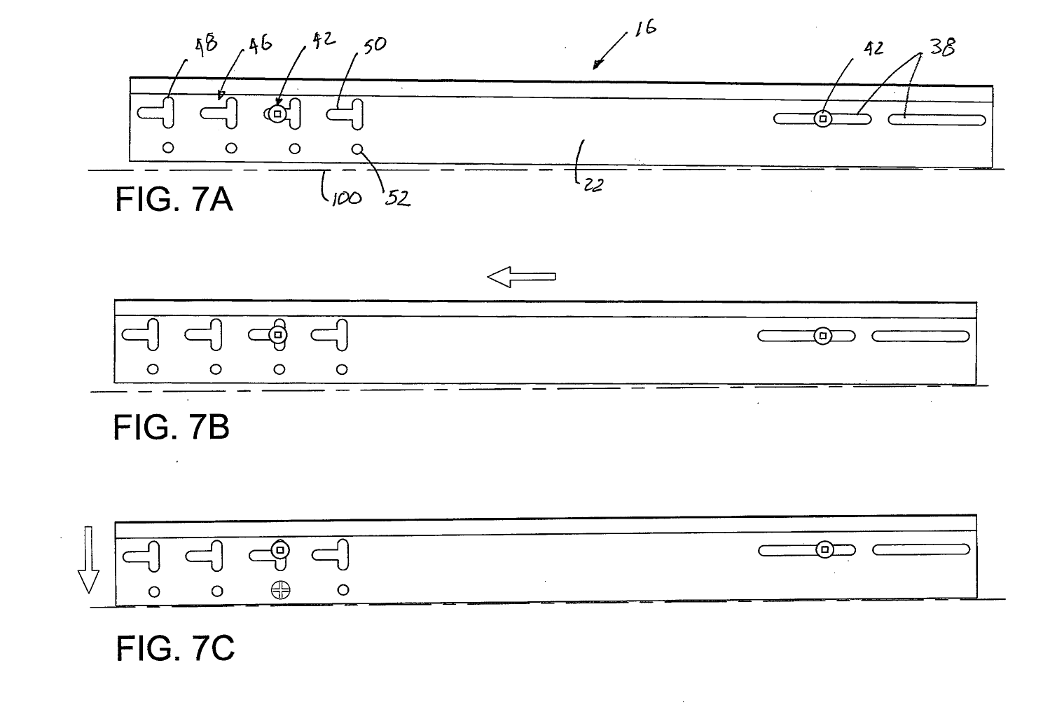

After the left securement screw 42 has been inserted through one of the T-shaped wall cleat slots, and specifically the slot leg 50 thereof, the wall cleat is leveled using a typical level. Once it has been leveled, the right hole location is marked and a second screw hole is drilled using the ⅛ drill bit that is provided in the package. The second end of the wall cleat is then installed using a second securement screw 42. In the configuration depicted in FIG. 1, both of the securement screws 42 are located in the horizontal portion of their respective wall cleat slots 38 and 46. This assumes that the wall cleat 16 has been attached to the wall 14 in the level orientation. Referring to FIGS. 7A, 7B and 7C, there may be seen a method for compensating for a non-level attachment of the wall cleat 16 to the wall surface 14. In the configuration depicted in FIG. 7A, the wall cleat 14 is elevated at the left, with the underlying dashed line 100 indicating a level line. The two securement screws 42 are loosened and the wall cleat is slid slightly to the left, as depicted by the arrow in FIG. 7B. In this position, the securement screw 42 positioned in the T-shape wall cleat slot 46 is now located at the junction of that slot's head 48 and leg 50. Since the left end of the wall cleat is too high, that end of the wall cleat can be lowered by movement of the left securement screw 42 up into the T-shaped wall cleat slot's head 48, as depicted in FIG. 7C. Now that the wall cleat 15 is level, the two securement screws can again be tightened. To ensure that the now properly located wall cleat 16 will not shift, as might be the case if the left securement screw 46 is at a location other than at the top of the slot head 48, a separate securement screw 42 is positioned in a level establishment aperture 58 directly underlying the head of the T-shaped slot.

Referring again to FIG. 3, it may be seen that the flat panel cleat flange 28 and the wall cleat flange 24 are separated from direct contact to each other by the imposition of the two part hook and loop or VELCRO® fastening components. This non-direct contact of the two flanges 24 and 28 provides a substantial sound and vibration propagation barrier. If the two flanges 24 and 28 were in direct contact, sounds and vibrations from the flat panel device would have a direct path of travel into the wall stud 90. However, the use of the hook and loop components 32 and 36 prevent such direct sound and vibration transmittal.

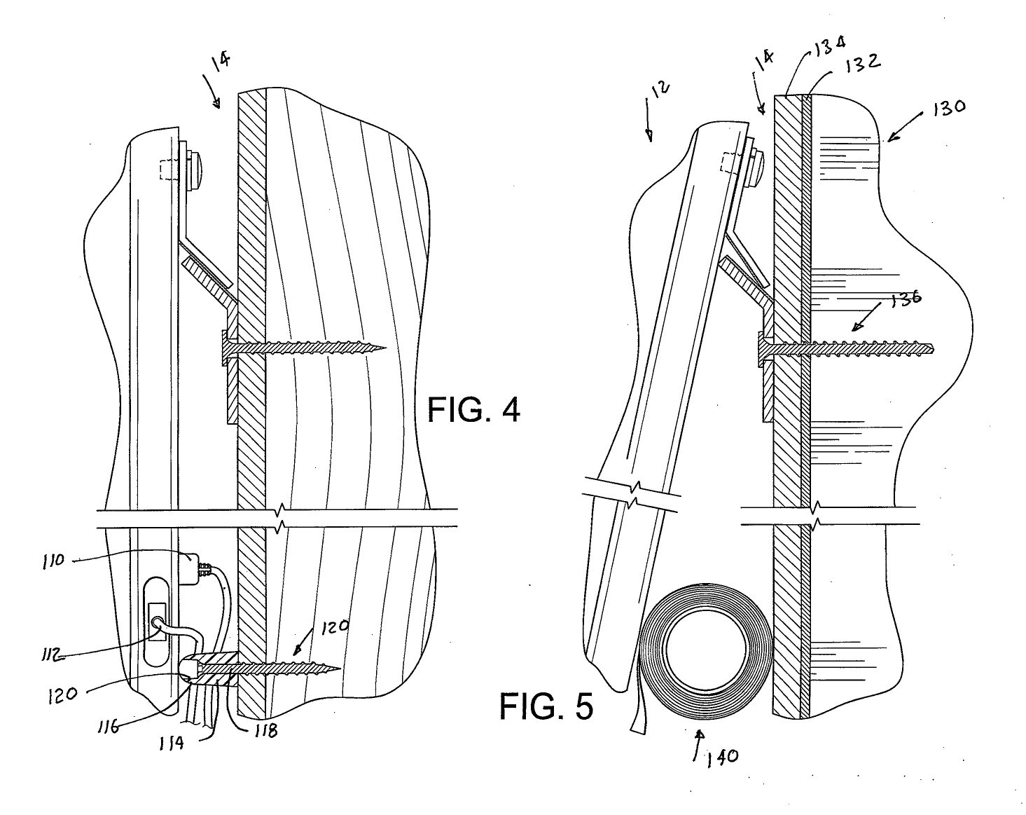

Referring now to FIG. 4, there may be seen a view generally similar to FIG. 3, but now also depicting the placement of a power cord 110 for the flat panel device and the placement of a typical HDMI cable 112. It will be understood that these cables 110 and 112 are intended to be schematic depictions of various cabling that is connected to a flat panel device and to a source of electrical power, to a cable box, to a DVR device, to a surround sound system and the like. None of these cables or pieces of equipment form a part of the subject invention but at least some of them are essential to the operation of a flat panel device. While the power cord 100 is depicted as being attached to the rear face of the flat panel device 12 and the HDMI cable 112 is shown as being secured to the side of the flat panel device 12, both of these placements are representative of various possible placements.

A space behind the flat panel device 12, to facilitate the positioning of a power cord 100 for example, is accomplished by the provision of the resilient wall spacer, generally at 20, as depicted in FIGS. 1 and 2, for example. The resilient wall spacer 20 has a generally cylindrical shaped body 114 which can be made of rubber or another similar resilient material. The spacer body 114 has a rounded head 116 and is provide with a through bore 118 that includes a countersink portion 120. A suitable wall spacer attachment screw 122 has a screw head 124 that is received in the bore 118 of the resilient wall spacer 20 and that can be screwed into a predrilled hole in the same wall stud 90 that receives one of the securement screws 42 used to secure the wall cleat plate.

The countersink 118 and the body 114 of the resilient wall spacer 20 ensures that the head 126 of the securement screw 122 will not contact the rear of the flat panel device 16. This further prevents sound and vibration from the flat panel device from traveling through the mounting system and into the walls of the building.

FIG. 5 is a depiction of the flat panel mounting system in accordance with the present invention and in which the wall cleat 16 has been attached to a wall surface 14 which includes underlying metal wall studs, such as the metal wall stud depicted at 130. The metal wall stud 130 typically has a metal wall stud face flange 132 to which wall panels 134 such as gypsum board and the like are attached. In this embodiment of the subject invention, a sheet metal securement screw 136 is used instead of the wood securement screw 96 which was used in connection with a wooden wall stud, as depicted in FIG. 3. Again, as was the procedure described in connection with FIG. 3, a pilot hole is drilled in the face flange 132 of the metal stud 130 using the 1/8 drill that is supplied with the flat panel mounting package. The wall cleat is fastened between two adjacent steel wall studs 130 and its level may be corrected, if necessary using the procedure which was discussed above.

FIG. 5 also illustrates another convenient aspect of the subject invention. Once the wall cleat 16 has been securely attached to the wall and the two flat panel cleats 18 have been attached to the rear of the flat panel device, using the provided screws and lock washers and utilizing the VESA® threaded bores that are placed in the back of virtually every flat panel device, the flat panel device is lifted by two people and is placed so that the flat panel cleat flanges 22 rest on the wall cleat flange 24. This positioning is maintained by the engagement of the hook and loop fastener components 32 and 36. While this hook and loop connection is sufficiently secure that the flat panel device cannot be knocked off the wall by casual contact, it is not so secure that it cannot be separated. As is depicted in FIG. 1, and as described above, the two flat panel cleats 18 do not have to be precisely spaced from either end of the wall cleat 24, since the object of this system is to allow the flat panel device to be centered, for example, on a wall and not necessarily between two wall studs. The length of the wall cleat 16 and the provision of the one component 32 of the hook and loop fastener along the entire length of the wall cleat flange 24 will allow for some flexibility in positioning of the two flat panel cleat flanges 28 along the wall cleat flange 24. Obviously, proper planning and stud location will aid in keeping any lateral offset between the flat panel device and the center of the wall cleat 16 at a minimum.

As is also depicted in FIG. 5, once the flat panel device 12 has been mounted on the wall, it is then necessary to make the appropriate power cord, cable box, DVR and ancillary equipment connections that may be required. To facilitate such connection, the lower surface of the flat panel device 12 can be moved away from the wall surface 14 to perform whatever connections that may be required. This is easily accomplished by using a prop, such as a roll of tape 140 to move the bottom of the flat panel device 12 away from the wall surface 14. The hook and loop components 32 and 36 which secure the wall cleat flange 24 and the flat panel cleat flange 26 to each other, can be partially separated during this movement of the bottom of the flat panel device 12 away from the wall surface 14. As seen in FIGS. 1 and 4, the separation will facilitate the running of the power cord 110, the HDMI cable 112 and any other required cables up the wall and into their connections on the flat panel device. The flat panel mounting system in accordance with the present invention is especially well suited for use with the WIRING SOLUTION™ system, which is another product of the applicant herein. That system utilizes a preformed channel assembly to route wires on the vertical surface of the wall. The WIRING SOLUTION component and the flat panel mounting system, which is marketed under the trademark CLEAT MOUNT, are intended to be used together to provide a very functional system for the home installer as well as for commercial installations.

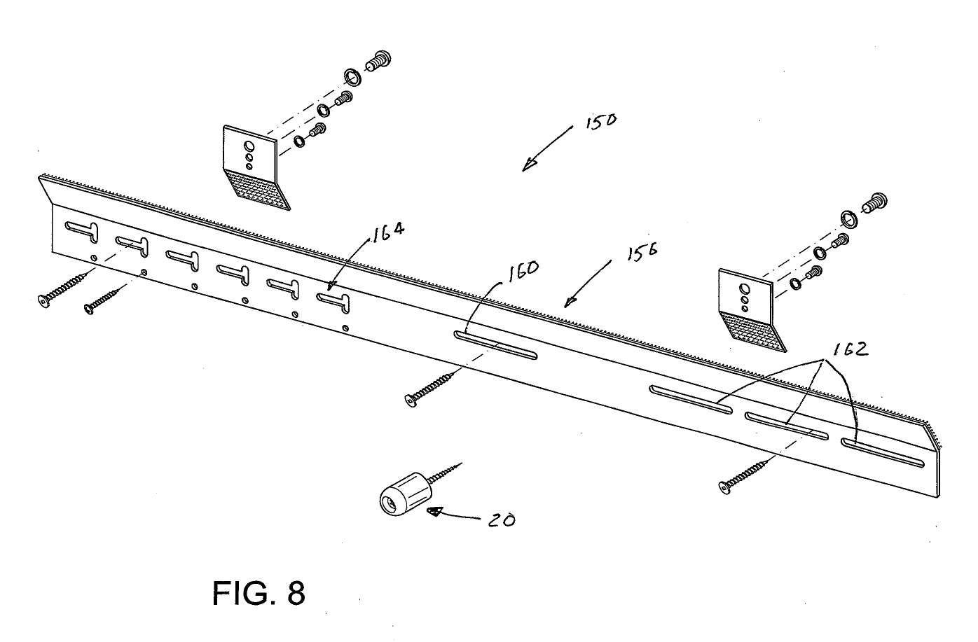

A modified flat panel mounting system, in accordance with the present invention, is depicted at 150 in FIG. 8. This system is intended primarily for larger flat panel devices which may be sufficiently heavy that it will be beneficial to provide a wall cleat 156 that is longer than the wall cleat 16 depicted in FIG. 1. The second embodiment of the flat panel mounting system uses essentially the same configuration of the flat panel cleat and extends the lengths of the wall cleat 156 so that it will be able to be mounted between three adjacent spaced wall studs, instead of between the two wall studs indicated in FIG. 1. The wall cleat 156 of the second preferred embodiment adds a third intermediate linear wall cleat slot 160 that is spaced between the now three linear wall cleat slots 162 and the now six T-shaped wall cleat slots 164. Although not specifically depicted in FIG. 8, it might be appropriate to provide a second intermediate wall cleat slot 160 to again increase the versatility of the wall cleat 150 so that it can be adapted to securement to three wall studs, either wood or metal, of a wide variety of spacings.

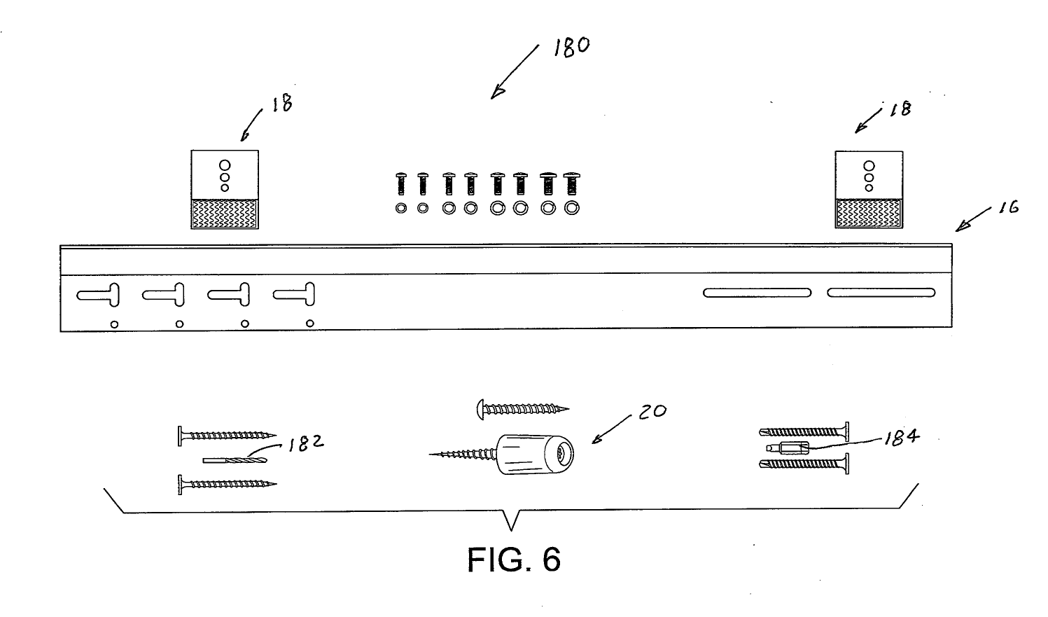

Turning to FIG. 6, there may be seen, generally at 180, a flat panel mounting package in accordance with the present invention. Such a package is primarily intended to be sold to an individual for use as a do it yourself or DIY kit. It includes all of the components that the DIY installer would need, other than common hand tools, to use the flat panel mounting system in accordance with the present invention. As may be seen in FIG. 6, the package 180 includes one wall cleat 16, two flat panel cleats 18, a resilient wall spacer 20 and a plurality of different size screws and lock washers 70-74 and 76-80 to secure the flat panel cleats to the rear of the appropriately sized flat panel device. Whereas FIG. 1 depicted three different sizes of screws and lock washers, FIG. 6 depicts four different sizes. This is because the middle hole 64 in each flat panel cleat plate can receive either M-5 or M-6 screws. Both such screw sizes are shown in FIG. 6. It will again be remembered that that the screw sizes recited in the discussion of this device are examples of different sizes of fasteners that can be supplied to allow the flat panel cleats 18 to be securely attached to the variety of flat panel devices which are on the market. The thread sizes and screw lengths are all intended to fit the largest possible number of flat panel devices.

Each package 180 is supplied with at least two cleat slot sized wood screws 96, two cleat slot sized sheet metal screws 136, and the one securement screw 42 that are usable with the level establishment aperture 52. Further, the package includes a ⅛ inch drill bit 182 and a #2 square driver 184 for the wood screws 196 and the sheet metal screws 136. These screws are preferably provided as POWERHEAD™ screws as provided by FASTCAP®. Such screws have a flat head with a socket sized to receive the #2 driver 184 which is supplied with the flat panel mounting package. The package, generally at 180 and as supplied to the installer and particularly to the DIY installer, contains all of the components that will be required to successfully install the wall cleat and the flat panel cleats and to accomplish the installation of a flat panel device on a wall surface.

The wall cleat and the flat panel cleats in accordance with the present invention are preferably made of a lightweight, strong metal, such as aluminum. It will be understood that other suitable metals and other non-metals could also be used to form the wall cleat and the flat panel cleats. Hook and loop fasteners and preferably VELCRO® brand hook and loop fasteners are preferred for joining of the wall cleat flange and the flat panel cleat flanges. While VELCRO® is the preferred hook and loop fastener, other similar hook and loop fasteners could also be used. The wall cleat flange and the flat panel cleat flanges are each formed at the same angle with respect to the plane defined by the wall cleat plate and by the flat panel cleat plates respectively. In a preferred embodiment, this angle is 45°. While this angle is preferred, it is not the only angle that will work. Other angles ranging as high as 90° could be used. The fastening elements such as the wood screws and the sheet metal screws depicted in the application are the typical securement devices for the vast majority of installations. However, it will be understood that the wall cleat can be installed to other types of walls such as plaster or concrete using an appropriate fastener. Since such an attachment is beyond the level of skill of a typical DIY installer, the disclosed package is provided from the manufacturer with the appropriate fasteners for the vast majority of applications.

The flat panel mounting system and package in accordance with the present invention provides all of the components that will typically be needed to mount a flat panel device, such as a television receiver or a video display panel, to a wall surface. While the preferred embodiment of the system and package has been fully and completely disclosed and described hereinabove, it will be apparent to one of skill in the art that various changes in, for example, the type of hook and loop fastener used, the lengths of the wood stud and metal stud engaging securement screws, the orientation of the flat panel device and the like could be made without departing from the true spirit and scope of the subject invention which is accordingly to be limited only by the appended claims.

What is claimed is:

1. A flat panel mounting system comprising:
a wall cleat having a length sufficient to span at least two spaced adjacent wall studs of a wall surface;
a wall cleat plate portion of said wall cleat and having a plurality of spaced first and second wall cleat plate mounting slots;
a wall cleat flange portion of said wall cleat and being angled at a first angle with respect to said wall cleat plate;
first and second flat panel cleats, each having a flat panel cleat plate;
at least one flat panel attachment fastener receiving hole in each said flat panel cleat plate and usable to secure each said flat panel cleat to a rear surface of a flat panel device;
a flat panel cleat flange on each said flat panel cleat and angled at said first angle with respect to said flat panel cleat plate; and
cooperating components of a hook and loop fastener system on each of said wall cleat flange and said flat panel cleat flanges whereby said wall cleat flange and said flat panel cleat flanges can be releasably secured together during mounting of the flat panel device to a surface of a wall.

2. The flat panel mounting system of claim 1 wherein said plurality of spaced first and second wall cleat plate mounting slots include at least one linear wall cleat slot at a first end of said wall cleat plate and extending in a horizontal direction of said wall cleat plate.

3. The flat panel mounting system of claim 2 wherein said plurality of spaced first and second wall cleat mounting slots include at least one T-shaped wall cleat mounting slot at a second end of said wall cleat plate and spaced from said at least one linear wall cleat slot.

4. The flat panel mounting system of claim 2 further including at least two of said linear wall cleat slots, spaced from each other at said first end of said wall cleat plate.

5. The flat panel mounting system of claim 3 further including at least first and second ones of said T-shaped wall cleat mounting slots at said second end of said wall cleat plate.

6. The flat panel mounting system of claim 3 wherein said at least one T-shaped wall cleat mounting slot includes a slot leg and a slot head.

7. The flat panel mounting system of claim 6 wherein said slot leg of said at least said one T-shaped wall cleat mounting slot extends in said longitudinal direction of said wall cleat plate.

8. The flat panel mounting system of claim 7 wherein each said slot head is positioned at a first end of each said slot leg and is transverse to said longitudinal direction of said wall cleat plate.

9. The flat panel mounting system of claim 8 further including a level establishment aperture on said wall cleat plate and located below a bottom portion of each said slot head.

10. The flat panel mounting system of claim 1 wherein there are a plurality of said flat panel attachment fastener receiving holes in each said flat panel cleat plate.

11. The flat panel mounting system of claim 10 wherein said plurality of said flat panel attachment fastener receiving holes in each said flat panel cleat plate are of different diameters.

12. The flat panel mounting system of claim 11 wherein said plurality of flat panel attachment fastener receiving holes are vertically aligned along a central vertical axis of each said flat panel cleat plate.

13. The flat panel mounting system of claim 1 further including a plurality of wood screws and a plurality of sheet metal screws each having a shank portion sized to pass through one of said first and second wall cleat mounting slots.

14. The flat panel mounting system of claim 13 wherein each said wood screw and each said sheet metal screw includes a screw head sized to be prevented from passing through a respective one of said first and second wall cleat mounting slots.

15. The flat panel mounting system of claim 1 further including a resilient wall spacer securable to one of said two spaced adjacent wall studs and beneath said wall cleat.

16. The flat panel mounting system of claim 15 wherein said resilient wall spacer includes a generally cylindrical spacer body with a countersunk spacer body head.

17. A flat panel mounting package comprising:
a wall cleat having a length sufficient to span at least two spaced adjacent wall studs of a wall surface;
a wall cleat plate portion of said wall cleat and having a plurality of spaced wall cleat plate mounting slots;
a wall cleat flange portion of said wall cleat and being angled at an angle with respect to said wall cleat plate;
first and second flat panel cleats each having a flat panel cleat plate;
at least one flat panel attachment fastener receiving hole in each said flat panel cleat plate;
a flat panel cleat flange on each said flat panel cleat and angled at said first angle with respect to said flat panel cleat plate;
cooperating components of a hook and loop fastening system on each of said wall cleat flange and said flat panel cleat flanges;
a plurality of securement screws sized to selectively be received in said mounting slots to secure said wall cleat to said wall studs;
a plurality of variously sized attachment fasteners adapted to be selectively received in said flat panel fastener receiving holes to secure said flat panel cleats to a rear surface of said flat panel; and
a resilient wall spacer securable to one of the wall studs and beneath said wall cleat attachable to the wall.

18. The flat panel mounting package of claim 17 further including a drill bit usable to drill securement screw receiving holes in the wall studs.

19. The flat panel mounting package of claim 17 further including a securement screw driving tool.
